(19) United States
(12) Patent Application Publication
(10) Pub. No.: US 2008/0048281 A1
(43) Pub. Date: Feb. 28, 2008

(54) IMAGE SENSOR AND FABRICATING METHOD THEREOF

(76) Inventor: Jae Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/782,165

(22) Filed: Jul. 24, 2007

(30) Foreign Application Priority Data
Aug. 23, 2006 (KR) 10-2006-0080136

(51) Int. Cl. H01L 31/0232; H01L 21/00

(52) U.S. Cl. 257/432; 438/69; 257/E31.127

(57) ABSTRACT

An image sensor according to embodiments may include a semiconductor substrate having a photo diode area formed thereon, a pre-metal dielectric (PMD) layer formed on the semiconductor substrate, at least one metal layer formed on the PMD layer, and a plurality of waveguides formed to penetrate through the metal layer and the PMD layer.

The present application claims priority under 35 U.S.C. 119 and 35 U.S.C. 365 to Korean Patent Application No. 10-2006-0080136 (filed on Aug. 23, 2006), which is hereby incorporated by reference in its entirety.

### BACKGROUND

Image sensors may be semiconductor devices that convert optical images into electric signals. An image sensor may be a charge coupled device (CCD) image sensor or a complementary metal oxide semiconductor (CMOS) image sensor. Image sensors may include photodiodes for detecting light and logic circuits for converting detected light into electrical data signals. Photo sensitivity of an image sensor may improve as more light is received by an image sensor.

Photo sensitivity of an image sensor may be reduced when light passing through a micro lens and a color filter passes several insulating layers. This may cause refraction and reflection in an interface. Accordingly, a portion of the light may be reflected or may disappear because it is not absorbed into a photo diode area. Hence, sensitivity may be reduced.

Photo sensitivity of an image sensor may be enhanced by increasing a rate, i.e. a sensitivity of converting incidence light signal into an electric signal.

### SUMMARY

Embodiments relate to an image sensor and a fabricating method thereof. Embodiments relate to an image sensor and a fabricating method thereof may improve sensitivity by effectively transferring an incidence light to a photo diode area.

According to embodiments, an image sensor may include a semiconductor substrate having a photo diode area, a pre-metal dielectric (PMD) layer formed on the semiconductor substrate, at least one metal layer formed on the PMD layer, and a plurality of waveguides formed to penetrate through the metal layer and the PMD layer.

According to embodiments, a method of fabricating an image sensor may include forming a pre-metal dielectric (PMD) layer on the semiconductor substrate having a photo diode area, forming at least one metal layer on the PMD layer, and forming a plurality of waveguides penetrating through the metal layer and the PMD layer.

### DRAWINGS

FIGS. 1 and 2 are drawings illustrating an image sensor and method of fabricating the same according to embodiments.

FIGS. 3 and 4 are drawings illustrating a waveguide formed in an image sensor according to embodiments.

### DETAILED DESCRIPTION

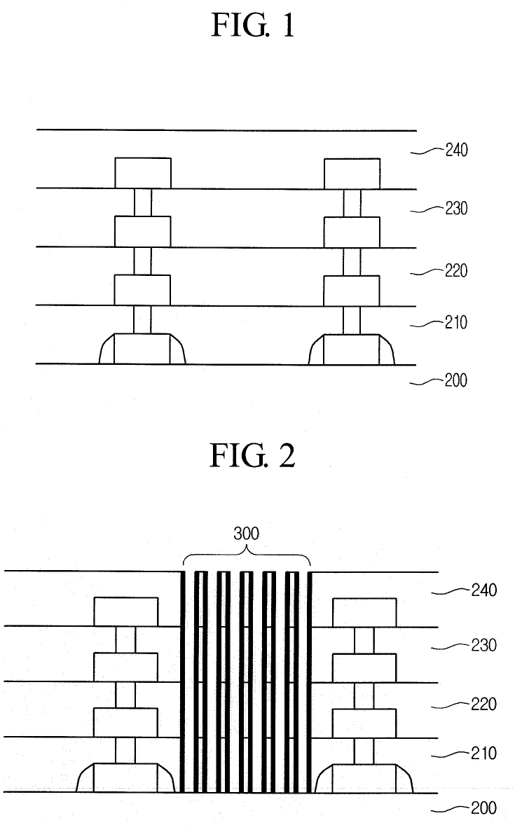

According to embodiments, referring to FIGS. 1 and 2, pre-metal dielectric (PMD) layer 210 may be formed on semiconductor substrate 200 having a photo diode area.

At least one metal layer may be formed on PMD layer 210. In embodiments, first metal layer 220, second metal layer 230, and third metal layer 240 may be formed as shown by way of example in FIG. 1. In embodiments, any number of metal layers may be present. For example, there may be more or fewer layers, according to designs, as compared to that shown in the embodiment of FIG. 1.

A plurality of waveguides 300 may be formed and may penetrate through third, second, and first metal layers 240, 230, 220, and PMD layer 210. According to embodiments, waveguides 300 may be formed over an upper portion of the photo diode area of semiconductor substrate 200.

According to embodiments, waveguide 300 may be formed as follows.

A plurality of through-holes, which may penetrate third, second, and first metal layers 240, 230, 220 and PMD layer 210, may be formed. In forming the through-hole, an etching may be performed up to the point where semiconductor substrate 200 may be exposed.

According to embodiments, a metal film may be formed on the product formed with the through-hole. In embodiments, the metal film may be formed on the inner wall and lower surface of the through-hole. In embodiments, the metal film may be formed of at least one of more materials selected from Ti, TiN, Cu, Al, Ta, TaN, W, Ag, Au, Co, Ni, or any combination or mixture thereof. The metal film may be deposited by any method, such as CVD, ALD, PVD, Evaporation, ECP, etc. In embodiments, the metal film may be formed to have a thickness of approximately 5 to 1000 Å.

In embodiments, the metal film formed on the lower surface of the through-hole may be removed. The metal film formed on the bottom portion may be removed by a PVD etching method having straightness (punch through method), according to embodiments.

Waveguide 300 may be formed by forming an insulating film on the product. In embodiments, a planarization for the insulating film may be performed by a CMP process after forming the insulating film.

Structures constituting waveguides 300 may be different depending on a size of the through-hole. A size of the through-hole may correspond to a size of waveguide 300.

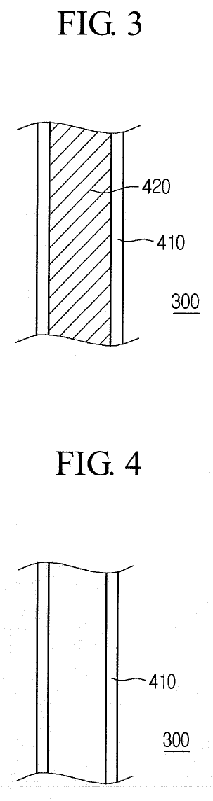

FIGS. 3 and 4 are drawings illustrating a waveguide formed in an image sensor according to embodiments.

In embodiments, if waveguide 300 is formed having a size of approximately 0.5 to 1.0 μm, the waveguide may be formed in a structure as shown in FIG. 3. In embodiments, metal film 410 may be formed on the side wall of waveguide 300, and insulating film 420 may be formed in an inside of metal film 410. Insulating film 420 may be formed by being filled or may be formed only in a portion of space without being filled, in the inside of metal film 410.

In embodiments, if waveguide 300 is formed having a size of 0.1 to 0.5 μm, waveguide 300 may be formed in a structure as shown in FIG. 4. In embodiments, metal film 410 may be formed on the side wall of waveguide 300, and the inside of metal film 410 may be formed with an empty space in a hollow shape without having the insulating film.

Although not shown in the drawings, in embodiments, a color filter may be formed on third metal layer 240. The color filter may selectively transmit light incident from upper layer corresponding to the wavelength band of the photo diode area of semiconductor substrate 200. In embodiments, a micro lens for light collection may be formed on the color filter.

According to embodiments, with an image sensor having the structure as described herein, the incidence light may be transferred to the photo diode area formed in semiconductor substrate 200 through waveguide 300. The light incident to waveguide 300 may be reflected on metal film 410 so that the light may be incident to the photo diode area. The light incident to waveguide 300 may arrive at the photo diode area of semiconductor substrate 200 without having loss. Accordingly, the incidence light may arrive at the photo diode area of semiconductor substrate 200 without having loss or with reduced loss, an a sensitivity of the image sensor may be increased.

According to embodiments, when a micro lens for light collection is formed, a process margin for forming the micro lens may be enlarged. Hence, the light incident to waveguide 300 may be transferred to the photo diode area of semiconductor substrate 200 so that the focal length of the micro lens may be focused on any portion of waveguide 300 from the inlet thereof to the inside thereof.

According to embodiments, a sensitivity may be improved by effectively transferring an incidence light to a photo diode area.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A device, comprising:
a semiconductor substrate having a photo diode area;
a pre-metal dielectric (PMD) layer formed over the semiconductor substrate;
at least one metal layer formed over the PMD layer; and
at least one waveguide formed to penetrate through the at least one metal layer and the PMD layer.

2. The device of claim 1, further comprising a color filter configured to selectively transmit light over the at least one waveguide.

3. The device of claim 1, wherein the at least one waveguide comprises a metal film formed on sidewalls of the at least one metal layer and the PMD layer.

4. The device of claim 3, further comprising an insulating film formed in an inside of the metal film.

5. The device of claim 4, wherein the waveguide has a size of 0.5 to 1.0 μm.

6. The device of claim 3, wherein an inside of the metal film is formed to leave an empty space between opposing sidewalls of the at least one metal layer and the PMD layer.

7. The device of claim 6, wherein the waveguide has a size of 0.1 to 0.5 μm.

8. The device of claim 3, wherein the metal film has a thickness of 5 to 1000 Å.

9. The device of claim 1, further comprising a through-hole penetrating the at least one metal layer and the PMD layer substantially over the photodiode area.

10. The device of claim 9, wherein the waveguide comprises a metal film formed on sidewalls of the through-hole.

11. The device of claim 10, further comprising an insulating film formed within the through-hole over the metal film.

12. A method, comprising:
forming a pre-metal dielectric (PMD) layer on a semiconductor substrate having a photo diode area;
forming at least one metal layer over the PMD layer; and
forming at least one waveguide penetrating through the at least one metal layer and the PMD layer.

13. The method of claim 12, wherein forming the at least one waveguide comprises:
forming at least one of through-hole penetrating through the at least one metal layer and the PMD layer;
forming a metal film on an inner wall and lower surface of the at least one through-hole; and
removing the metal film formed on the lower surface of the at least one through-hole.

14. The method of claim 13, further comprising forming an insulating film over the metal film.

15. The method of claim 14, wherein the insulating film is formed over an inside of the metal film.

16. The method of claim 15, wherein a size of the waveguide is formed to be 0.5 to 1.0 μm.

17. The method of claim 13, wherein an inside of the metal film is formed to leave an empty space between opposing sidewalls of the at least one through-hole.

18. The method of claim 17, wherein a size of the waveguide is formed to be 0.1 to 0.5 μm.

19. The method of claim 13, wherein the at least one through-hole is formed to be substantially over the photo diode area of the semiconductor substrate.

20. The method of claim 12, comprising forming a color filter over the at least one waveguide to selectively transmit light to the photo diode area.
